(19) United States
(12) Patent Application Publication
(10) Pub. No.: US 2025/0208174 A1
(43) Pub. Date: Jun. 26, 2025

(54) VOLTAGE MONITORING CIRCUIT AND VOLTAGE MONITORING METHOD

(71) Applicant: FANUC CORPORATION, Minamitsuru-gun, Yamanashi (JP)

(72) Inventor: Jun OKAMOTO, Minamitsuru-gun, Yamanashi (JP)

(21) Appl. No.: 18/846,468

(22) PCT Filed: May 12, 2022
(86) PCT No.: PCT/JP2022/020054

§ 371 Date: Sep. 12, 2024

(51) Int. Cl. G01R 19/00

(52) U.S. Cl. CPC G01R 19/0038

(57) ABSTRACT

A voltage monitoring circuit includes a reference voltage generation unit that generates a fluctuating reference voltage that periodically changes between a first reference voltage and a smaller second reference voltage, and a comparison unit that compares the fluctuating reference voltage and voltage being monitored, and switches the output level on the basis of the relative magnitudes of the fluctuating reference voltage and the voltage being monitored. The reference voltage generation unit may generate the first reference voltage and the second reference voltage by varying the resistor divider ratio of a constant voltage. The comparison unit may include a plurality of comparators to which a plurality of voltages being monitored are respectively inputted.

### TECHNICAL FIELD

The present invention relates to a voltage monitoring circuit and a voltage monitoring method for comparing a reference voltage with a monitored voltage so as to switch an output level based on relative magnitudes of the reference voltage and the monitored voltage.

### BACKGROUND ART

A voltage monitoring circuit is described, for example, in Patent Document 1 and Patent Document 2. In Patent Document 1, an abnormality detection apparatus for detecting abnormality of a plurality of voltage monitoring devices is described, the plurality of voltage monitoring devices being provided for a plurality of battery blocks of a battery pack, respectively, and including comparison units that compare a threshold with block voltages of the battery blocks and control units that control the threshold. The abnormality detection apparatus includes an acquisition unit, a decision unit, an output unit, and a detection unit. The acquisition unit acquires the block voltages. The decision unit decides the threshold based on the block voltages. In order that a duty signal corresponding to the threshold is outputted from an output terminal of the control unit, the output unit outputs an indication signal indicating a signal level of the duty signal, to the control unit. The detection unit detects abnormality of the voltage monitoring devices according to a result of the comparison that the comparison unit performs based on the threshold.

In Patent Document 2, a power source voltage monitoring circuit including an abnormality detection unit and a voltage changing unit is described. The abnormality detection unit detects a voltage according to a power source voltage, and detects abnormality of the power source voltage based on a result of comparison between the detected voltage and a reference voltage. The voltage changing unit changes the detected voltage or the reference voltage to a voltage based on which abnormality within an abnormality detection range of the abnormality detection unit can be detected.

### CITATION LIST

### Patent Document

Patent Document 1: Japanese Unexamined Patent Application, Publication No. 2019-60657
Patent Document 2; Japanese Unexamined Patent Application, Publication No. 2016-142597

### DISCLOSURE OF THE INVENTION

### Problems to be Solved by the Invention

A voltage monitoring circuit that compares a reference voltage with a monitored voltage to switch an output level (between an “H” level and an “L” level) based on relative magnitudes of the reference voltage and the monitored voltage determines the monitored voltage to be abnormal, for example, in a case where the monitored voltage becomes equal to or lower than the reference voltage, and the output level switches from the “H” level to the “L” level. The switching of the output level of the voltage monitoring circuit, however, is also caused by abnormality of the voltage monitoring circuit. Therefore, it is not possible to determine whether the switching of the output level of the voltage monitoring circuit has been caused by abnormality of the monitored voltage or by abnormality of the voltage monitoring circuit. A circuit for detecting abnormality of the voltage monitoring circuit can be separately provided, which leads to an increase in costs. Therefore, a voltage monitoring circuit and a voltage monitoring method are desired which are capable of determining normality/abnormality of a monitored voltage and the voltage monitoring circuit without having to be provided with another circuit for detecting abnormality of the voltage monitoring circuit separately from the voltage monitoring circuit.

### Means for Solving the Problems

(1) A first aspect of the present disclosure is a voltage monitoring circuit, the voltage monitoring circuit including a reference voltage generation unit configured to generate a variable reference voltage, the variable reference voltage periodically changing between a first reference voltage and a second reference voltage lower than the first reference voltage; and a comparison unit configured to compare the variable reference voltage with a monitored voltage and switch an output level based on relative magnitudes of the variable reference voltage and the monitored voltage.
(2) A second aspect of the present disclosure is a voltage monitoring method of a voltage monitoring circuit, the voltage monitoring method including causing a switching element to input a periodically changing variable reference voltage to a comparison unit, by switching between a first reference voltage and a second reference voltage lower than the first reference voltage; and causing a comparison unit to compare the variable reference voltage with a monitored voltage and to switch an output level based on relative magnitudes of the variable reference voltage and the monitored voltage.

### Effects of the Invention

According to each aspect of the present disclosure, it becomes possible to determine normality/abnormality of a monitored voltage and a voltage monitoring circuit by an output of the voltage monitoring circuit, without having to provide another circuit for detecting abnormality of the voltage monitoring circuit separately from the voltage monitoring circuit.

### BRIEF DESCRIPTION OF THE DRAWINGS

FIG. 1 is a block diagram showing a voltage monitoring circuit of a first embodiment of the present disclosure.

FIG. 2 is a waveform diagram showing operation of the voltage monitoring circuit of the first embodiment of the present disclosure.

FIG. 3 is a block diagram showing a voltage monitoring circuit to be described as a comparative example.

FIG. 4 is a waveform diagram showing operation of the voltage monitoring circuit of the comparative example.

FIG. 5 is a block diagram for illustrating a failure that occurs in the voltage monitoring circuit of the comparative example.

FIG. 6 is a waveform diagram showing operation of the voltage monitoring circuit of the comparative example when a failure has occurred in the voltage monitoring circuit of the comparative example result.

FIG. 7 is a waveform diagram showing operation of the voltage monitoring circuit of the comparative example when a failure has occurred in the voltage monitoring circuit of the comparative example.

FIG. 8 is a block diagram for illustrating a failure that occurs in the voltage monitoring circuit of the first embodiment of the present disclosure.

FIG. 9 is a waveform diagram showing operation of the voltage monitoring circuit of the first embodiment of the present disclosure when a failure has occurred in the voltage monitoring circuit of the first embodiment.

FIG. 10 is a waveform diagram showing operation of the voltage monitoring circuit of the first embodiment of the present disclosure when a failure has occurred in the voltage monitoring circuit of the first embodiment.

FIG. 11 is a block diagram showing a voltage monitoring circuit of a second embodiment of the present disclosure.

FIG. 12 is a waveform diagram showing operation of the voltage monitoring circuit of the second embodiment of the present disclosure.

FIG. 13 is a block diagram showing a modification of the voltage monitoring circuit of the second embodiment of the present disclosure.

FIG. 14 is a block diagram showing a voltage monitoring circuit of a third embodiment of the present disclosure.

FIG. 15 is a waveform diagram showing operation of the voltage monitoring circuit of the third embodiment of the present disclosure.

FIG. 16 is a waveform diagram showing operation of the voltage monitoring circuit of the first embodiment of the present disclosure when a reference voltage Vref1 is set to a value exceeding an upper limit of a fluctuation range of a monitored voltage Vx.

FIG. 17 is a waveform diagram showing operation of the voltage monitoring circuit of the first embodiment of the present disclosure when a reference voltage Vref2 is set to a value below a lower limit of the fluctuation range of a monitored voltage Vx.

### PREFERRED MODE FOR CARRYING OUT THE INVENTION

Embodiments of the present disclosure will be described below in detail with reference to the drawings.

### FIRST EMBODIMENT

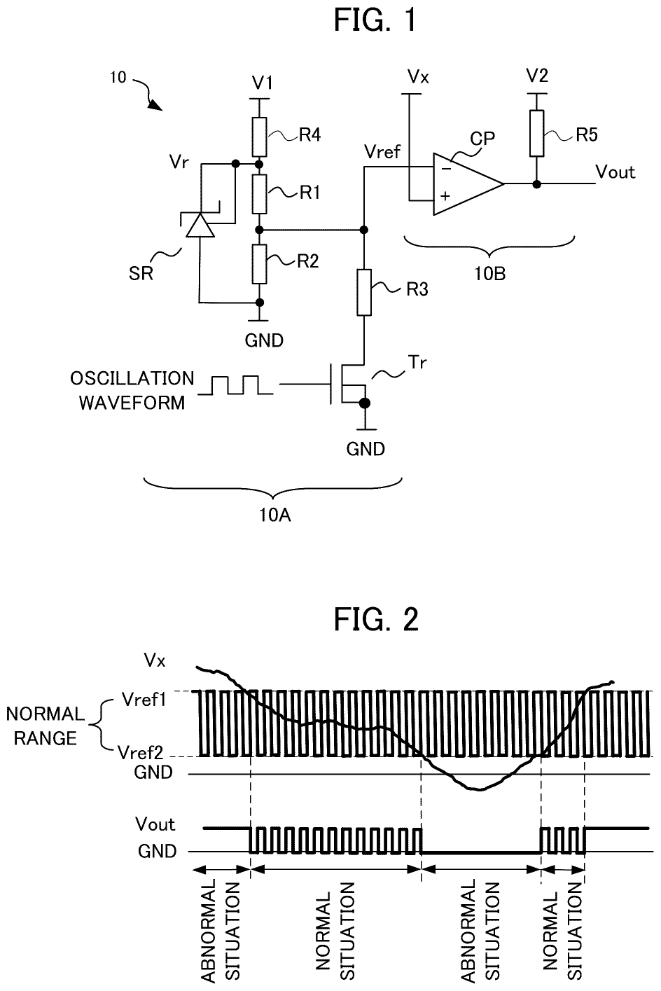

FIG. 1 is a block diagram showing a voltage monitoring circuit of a first embodiment of the present disclosure. FIG. 2 is a waveform diagram showing operation of the voltage monitoring circuit of the first embodiment of the present disclosure. A voltage monitoring circuit 10 is provided with a reference voltage generation unit 10A and a comparison unit 10B. The reference voltage generation unit 10A includes a shunt regulator SR, resistors R1, R2, R3, and R4, and an MOS transistor Tr functioning as a switching element. The comparison unit 20B includes a comparator CP and a resistor R5. The comparison unit 20B switches an output level based on relative magnitudes of a variable reference voltage and a monitored voltage as described later.

The shunt regulator SR applies voltages across terminals at both ends of the resistor R1 and the resistor R2 that are. connected in series so that the terminal of the resistor R2 serve as GND, and the voltage of the terminal of the resistor R1 becomes a constant voltage Vr. The terminal of the resistor R1 to which the constant voltage Vr is applied is connected to one terminal of the resistor R4. To the other terminal of the resistor R4, a voltage V1 is applied. A connection point between the resistor R1 and the resistor R2 is connected to one terminal of the resistor R3 and an inverting input terminal (−) of the comparator CP. The other terminal of the resistor R3 is connected to the drain of the MOS transistor Tr. The source of the MOS transistor Tr is connected to GND. The MOS transistor Tr is on/off controlled by an oscillation signal inputted to the gate.

A variable reference voltage Vref inputted to the inverting input terminal (−) of the comparator CP periodically switches between a reference voltage Vref1 serving as a first reference voltage and a reference voltage Vref2 serving as a second reference voltage in accordance with turning on/off of the MOS transistor Tr and periodically changes, Specifically, when the MOS transistor Tr in an off state, the reference voltage Vref1 is inputted to the inverting input terminal (−) of the comparator CP. The reference voltage Vref1 is a voltage generated by resistor division of the constant voltage Vr with the resistor R1 and the resistor R2. Specifically, when the MOS transistor Tr in an on state, the reference voltage Vref2 (Vref2<Vref1) is inputted to the inverting input terminal (−) of the comparator CP. The reference voltage Vref2 is a voltage generated by resistor division of the constant voltage Vr with the resistor R1 and a combined resistance of the resistors R2 and R3 connected in parallel. The reference voltage Vref1 and the reference voltage Vref2 are represented by Formula 1 (Formula 1 below). The reference voltage Vref1 and the reference voltage Vref2 are generated by changing the resistor divider ratio for the constant voltage Vr.

$$V ref 1 = \frac{Vr \times R 2}{( R 1 + R 2 )} \qquad [ Formula 1 ]$$

$$Vref 2 = \frac{Vr \times ( \frac{R 2 \times R 3}{R 2 + R 3} )}{( R 1 + \frac{R 2 \times R 3}{R 2 + R 3} )}$$

The comparator CP compares the variable reference voltage Vref inputted to the inverting input terminal (−) with a monitored voltage Vx inputted to a non-inverting input terminal (+). One terminal of the resistor RS is connected to the output side of the comparator CP, and a voltage V2 is applied to the other terminal of the resistor RS. An output voltage Vout is outputted from the comparator CP. As shown in FIG. 2, when the monitored voltage Vx is between the reference voltage Vref1 and the reference voltage Vref2 (Vref1>Vx>Vref2), the output voltage Vout has a pulse waveform. When the monitored voltage Vx is equal to or higher than the reference voltage Vref1 (Vx≥Vref1), the output voltage Vout is a fixed voltage at an “H” level. When the monitored voltage Vx is equal to or lower than the reference voltage Vref2 (Vx≤Vref2), the output voltage Vout is a fixed voltage at an “L” level (GND).

In the present embodiment, the voltage monitoring circuit 10 operates so that, when both of the monitored voltage Vx and the voltage monitoring circuit are normal, the output voltage Vout has a pulse waveform and, when abnormality of the monitored voltage Vx or abnormality of the voltage monitoring circuit itself occurs, the output voltage Vout becomes a fixed voltage at the “H” level or the “L” level.

Hereinafter, the operation of the voltage monitoring circuit of the present embodiment will be further described in comparison with a voltage monitoring circuit that is not provided with the resistor R3 or the MOS transistor Tr.

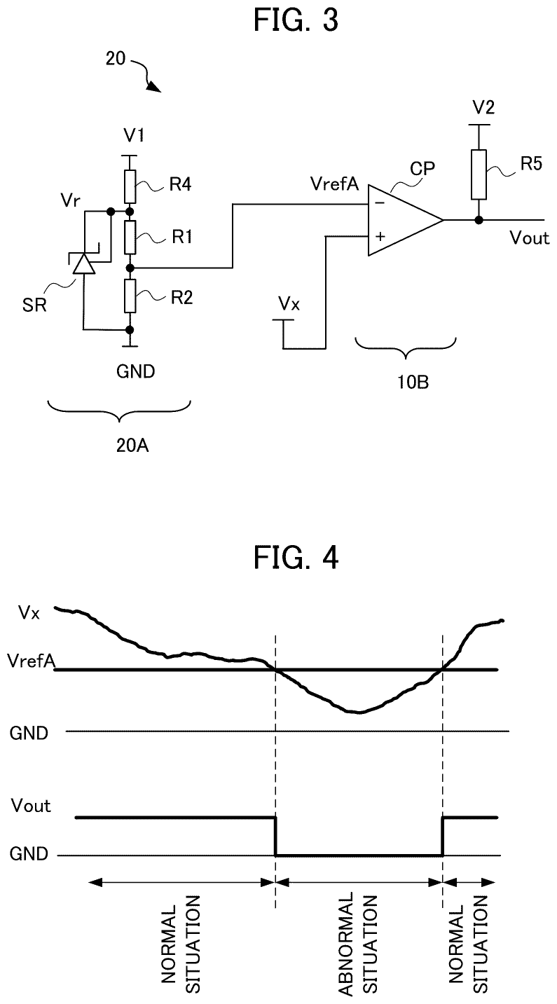

First, operation of the voltage monitoring circuit that is not provided with the resistor R3 or the MOS transistor Tr as a comparative example will be described. FIG. 3 is a block diagram showing the voltage monitoring circuit as the comparative example. FIG. 4 is a waveform diagram showing the operation of the voltage monitoring circuit of the comparative example. A voltage monitoring circuit 20 shown in FIG. 3 is different from the voltage monitoring circuit 10 shown in FIG. 1 in that the reference voltage generation unit 10A shown in FIG. 1 is replaced with a reference voltage generation unit 20A from which the resistor R3 and the MOS transistor Tr are removed, and that a reference voltage is a fixed reference voltage VrefA. In the voltage monitoring circuit 20, the comparator CP compares the reference voltage VrefA with the monitored voltage Vx and, when the monitored voltage Vx is equal to or higher than the reference voltage VrefA, the comparison unit 10B outputs the output voltage Vout at the “B” level. When the monitored voltage Vx is lower than the reference voltage VrefA, the comparison unit 10B outputs the output voltage Vout at the “L” level (GND). When the output voltage Vout is at the “H” level, the monitored voltage Vx is determined to be normal. When the output voltage Vout is at the “L” level (GND), the monitored voltage Vx is determined to be abnormal.

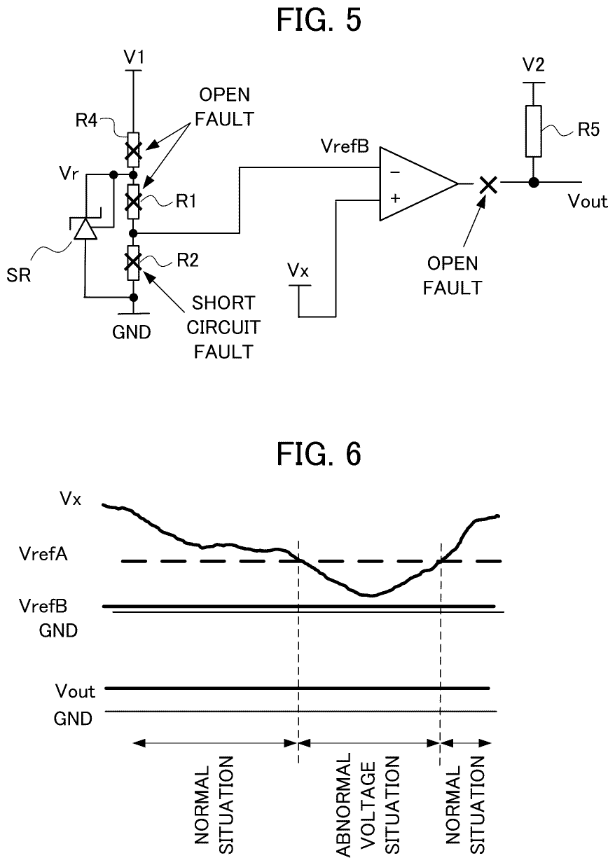

As described below, however, there may be a case where, when a failure occurs in the voltage monitoring circuit 20, the output voltage Vout is at the “H” level, even if the monitored voltage Vx becomes lower than the reference voltage VrefA, and the monitored voltage Vx is determined to be normal. As shown in FIG. 5, there may be a case where a failure represented by “x” in FIG. 5 occurs in the reference voltage generation unit 20A of the voltage monitoring circuit 20, and the reference voltage VrefA becomes equal to a reference voltage VrefB (VredB=0 V). FIG. 5 shows a case where in the reference voltage generation unit 20A, an open fault represented by “x” in the diagram has been caused in the resistor R1 and/or the resistor R4 due to an implementation error or open destruction, or a short circuit fault represented by “x” in the diagram has been caused in the resistor R2 due to a solder bridge. When the reference voltage VrefB is inputted to the inverting input terminal (−) of the comparator CP, the monitored voltage Vx is equal to or higher than the reference voltage VrefB even if it is lower than the reference voltage VrefA to which it originally should be set, and the output voltage Vout is at the “H” level, as shown in FIG. 6. Therefore, the monitored voltage Vx is determined to be normal.

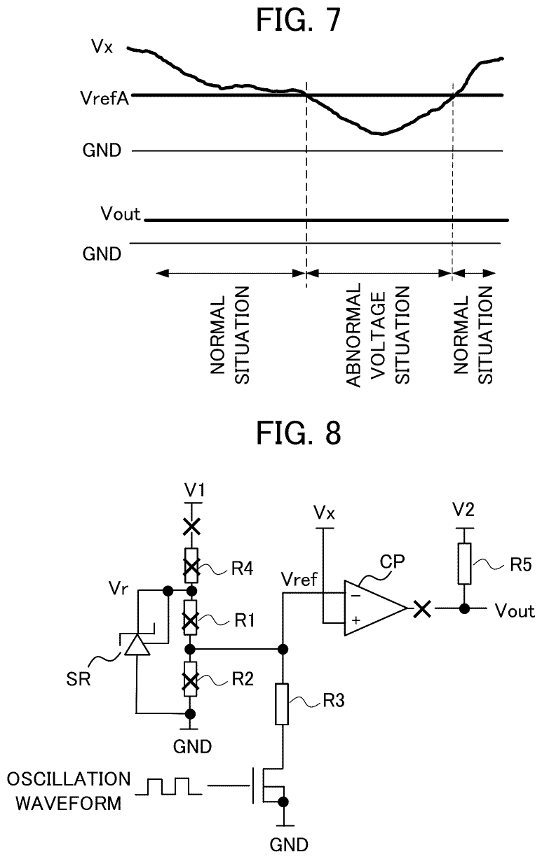

Further, as shown in FIG. 5, there may be a case where a failure represented by “x” in the diagram occurs in the comparison unit 10B of the voltage monitoring circuit 20, and the output voltage Vout increases to the “H” level. FIG. 5 shows a case where a soldering fault has occurred on the output side of the comparator CP of the comparison unit 10B, and an open fault represented by “x” in the diagram has occurred. When an open fault occurs on the output side of the comparator CP, the output voltage Vout is at the “H” level irrespective of a result of comparison between the monitored voltage Vx and the reference voltage VrefA as shown in FIG. 7, and the monitored voltage Vx is determined to be normal.

Next, operation of the voltage monitoring circuit of the present embodiment will be described. By setting a reference voltage to the variable reference voltage Vref that periodically switches between the reference voltage Vref1 and the reference voltage Vref2, the voltage monitoring circuit 10 of the present embodiment causes the output voltage Vout to have a pulse waveform when the monitored voltage Vx is within a normal range, and the voltage monitoring circuit is normal. When the monitored voltage Vx is outside the normal range or when there is abnormality in the voltage monitoring circuit, the output voltage Vout has a fixed waveform, and abnormality of the monitored voltage Vx or abnormality of the voltage monitoring circuit can be detected. Thereby, safe operation of equipment can be ensured.

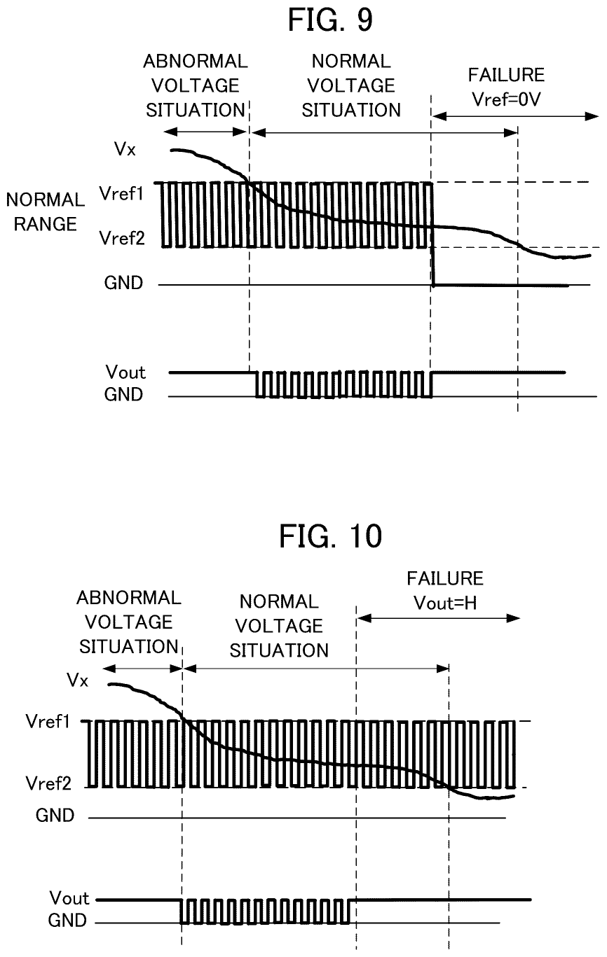

As shown in FIG. 8, there may be a case where a failure represented by “x” in the diagram occurs in the reference voltage generation unit 10A of the voltage monitoring circuit 10 similarly to the voltage monitoring circuit 20 of the comparative example shown in FIG. 5, and the reference voltage Vref becomes 0 V. FIG. 8 shows a case where in the reference voltage generation unit 10A, an open fault represented by “x” in the diagram has been caused by an implementation error or open destruction in the resistor R1 and/or the resistor R4, or a short circuit fault represented by “x” in the diagram has been caused by a solder bridge of the resistor R2. When a failure represented by “x” in the diagram occurs in the reference voltage generation unit 10A of the voltage monitoring circuit 10, and the voltage of the connection point between the resistor R1 and the resistor R2 becomes 0 V, 0 V (GND) is applied to the inverting input terminal (−) of the comparator CP even if the MOS transistor Tr is turned on/off. Since the monitored voltage Vx exceeds 0 V, the output voltage Vout becomes a fixed voltage at the “H” level, as shown in FIG. 9. Therefore, it is determined that the monitored voltage Vx is outside the normal range or that there is abnormality in the voltage monitoring circuit.

Further, as shown in FIG. 8, there may be a case where a failure represented by “x” in the diagram occurs in the comparison unit 10B of the voltage monitoring circuit 10, and the output voltage Vout increases to the “H” level, similarly to the comparative example. FIG. 8 shows a case where a soldering fault has occurred on the output side of the comparator CP of the comparison unit 10B, and an open fault represented by “x” in the diagram has occurred. When an open fault occurs on the output side of the comparator CP, the output voltage Vout becomes a fixed voltage at the “H” level irrespective of a result of comparison between the monitored voltage Vx and the variable reference voltage Vref as shown in FIG. 10, and it is determined that the monitored voltage Vx is outside the normal range or that there is abnormality in the voltage monitoring circuit.

When the failure in the voltage monitoring circuit 10 represented by “x” in FIG. 8 does not occur, and the monitored voltage Vx becomes equal to or lower than the reference voltage Vref2, the output voltage Vout becomes a fixed voltages at the “L” level, and it is determined that there is abnormality in the monitored voltage Vx.

According to the voltage monitoring circuit of the present embodiment described above, it is possible to detect abnormality of the monitored voltage Vx or the voltage monitoring circuit, and it is possible to ensure safe operation of equipment. According to the voltage monitoring circuit of the present embodiment, it is possible to realize periodic change between the two reference voltages Vref1 and Vref2 by adding resistors and a switching element and using a square wave of a switching power source or the like as an oscillation waveform. Therefore, it is possible to realize comparison between the monitored voltage Vx and the two reference voltages Vref1 and Vref2 by one comparator. The voltage monitoring circuit of the present embodiment has the advantage of being able to reduce the number of used comparators that may cause a failure, in comparison with the case of performing comparison between the monitored voltage Vx and the two reference voltages Vref1 and Vref2 using two comparators. Furthermore, it is possible to check normal operation of the voltage monitoring circuit without adding a circuit for checking the normal operation of the voltage monitoring circuit.

### SECOND EMBODIMENT

The voltage monitoring circuit 10 of the first embodiment operates so that, when both of the monitored voltage Vx and the voltage monitoring circuit are normal, the output voltage Vout has a pulse waveform and, when abnormality of the monitored voltage Vx or abnormality of the voltage monitoring circuit occurs, the output voltage Vout becomes a fixed voltage at the “H” level or the “L” level. A voltage monitoring circuit of the present embodiment includes a determination circuit for determining whether the output voltage Vout is a pulse waveform voltage or a fixed voltage.

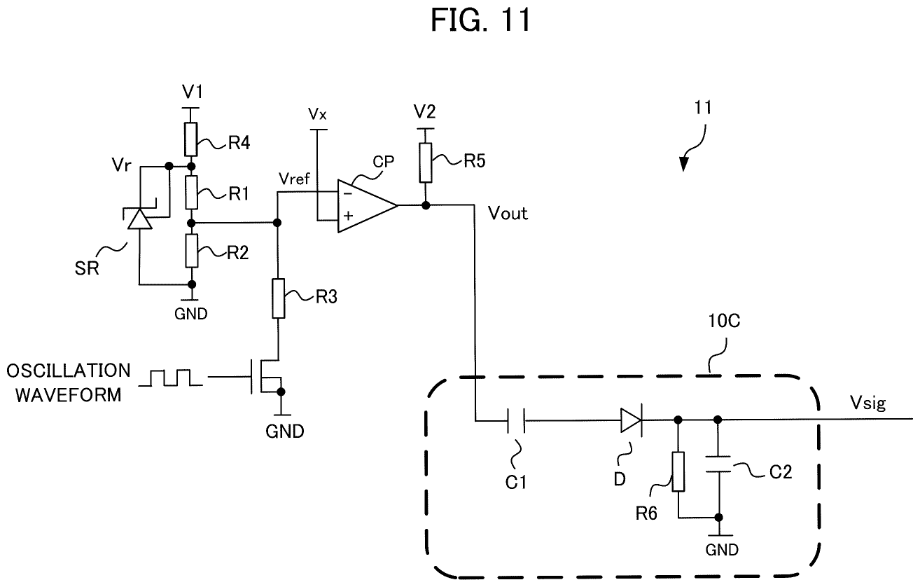

FIG. 11 is a block diagram showing the voltage monitoring circuit of the second embodiment of the present disclosure. A voltage monitoring circuit 11 of the present embodiment includes a determination circuit 10C at the subsequent stage of the comparison unit 10B of the voltage monitoring circuit 10 shown in FIG. 1, and the determination circuit 10C determines whether the output voltage Vout is a pulse waveform voltage or a fixed voltage. The determination circuit 10C includes an AC coupling capacitor C1, a diode D, a resistor R6, and a smoothing capacitor C2. One terminal of the AC coupling capacitor C1 is connected to an output terminal of the comparator CP and one terminal of the resistor R5, and the other terminal is connected to an anode terminal of the diode D. A cathode terminal of the diode D is connected to one terminal of the resistor R6 and one terminal of the smoothing capacitor C2. The other terminal of the resistor R6 and the other terminal of the smoothing capacitor C2 are connected to GND.

The AC coupling capacitor C1 causes a current to flow when there is change in the voltage of the output voltage Vout, and the diode D causes a current to flow when the electric potential of the anode terminal reaches the “H” level. When the output voltage Vout becomes a pulse waveform voltage and changes from GND to the “H” level, a current flows via the AC coupling capacitor C1 and the diode D, and the voltage of one terminal of the smoothing capacitor C2 increases to the “H” level. When the output voltage Vout is a fixed voltage, the AC coupling capacitor C1 does not cause a current to flow. Therefore, one terminal of the smoothing capacitor C2 serves as GND via the resistor R6.

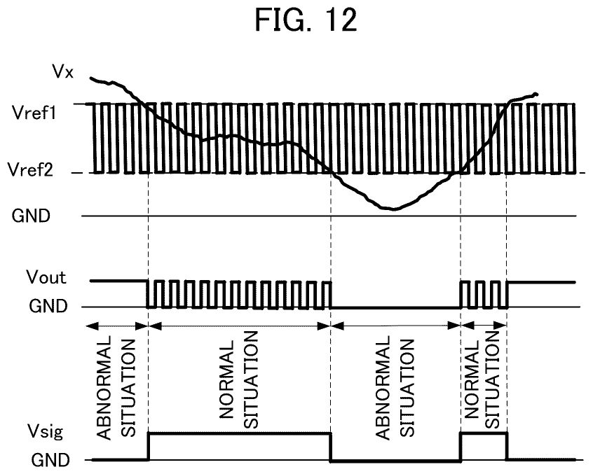

As shown in FIG. 12, when both of the monitored voltage Vx and the voltage monitoring circuit are normal, the output voltage Vout has a pulse waveform and, when abnormality of the monitored voltage Vx or abnormality of the voltage monitoring circuit itself occurs, the output voltage Vout becomes a fixed voltage at the “H” level or the “L” level. Therefore, a determination signal Vsig outputted from one terminal of the smoothing capacitor C2 indicates the “H” level when both of the monitored voltage Vx and the voltage monitoring circuit are normal and indicates GND when abnormality of the monitored voltage Vx or abnormality of the voltage monitoring circuit itself occurs.

### Modification of Determination Circuit

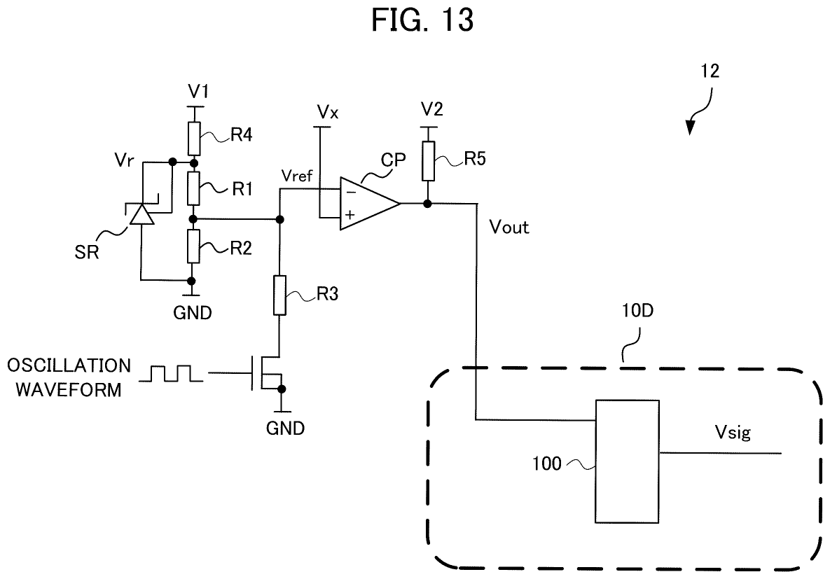

The determination circuit is not limited to the configuration of the determination circuit 10C shown in FIG. 11, and other configurations are also possible. FIG. 13 is a block diagram showing a modification of the voltage monitoring circuit of the second embodiment of the present disclosure. A voltage monitoring circuit 12 of the present embodiment includes a determination circuit 10D instead of the determination circuit 10C of the voltage monitoring circuit 11 shown in FIG. 11. The determination circuit 10D includes a counter IC 100. The counter IC 100 counts the number of inputted pulses of the output voltage Vout and is reset when pulses are not inputted any more. A determination signal Vsig outputted from the counter IC 100 has the same waveform as the determination signal Vsig shown in FIG. 12.

### Third Embodiment

The voltage monitoring circuit 10 of the first embodiment has been described with regard to the case of inputting the monitored voltage Vx and the variable reference voltage Vref to the comparator CP. A voltage monitoring circuit 13 of the present embodiment inputs two different monitored voltages to non-inverting input terminals (+) of two comparators, respectively, and inputs the common variable reference voltage Vref to inverting input terminals (−) of the two comparators.

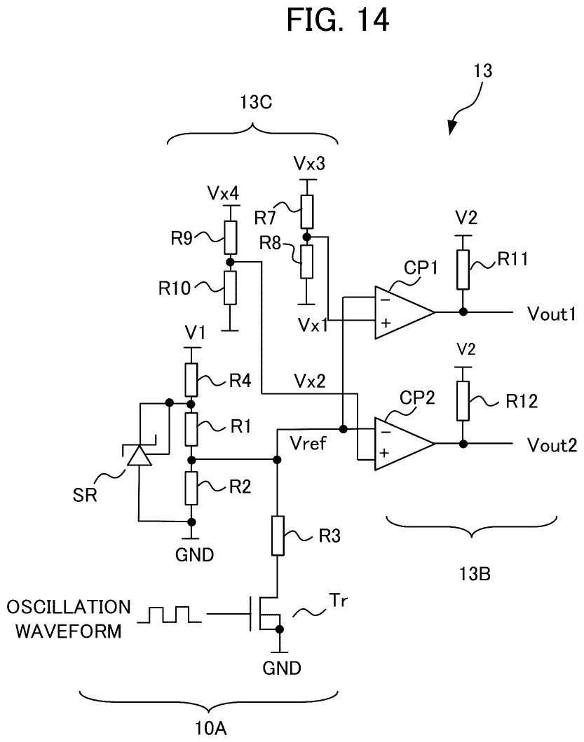

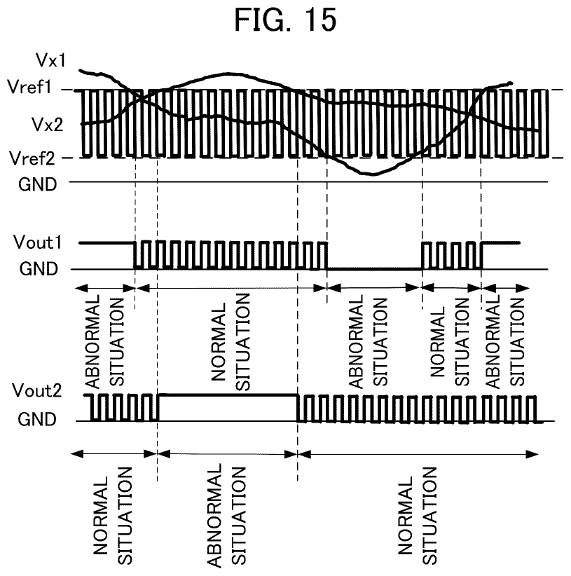

FIG. 14 is a block diagram showing the voltage monitoring circuit of the third embodiment of the present disclosure. FIG. 15 is a waveform diagram showing operation of the voltage monitoring circuit of the third embodiment of the present disclosure. In the voltage monitoring circuit 13 of FIG. 14, the same components as those of the voltage monitoring circuit 10 of FIG. 1 will be given the same reference signs, and description thereof will be omitted. The voltage monitoring circuit 13 of the present embodiment includes the reference voltage generation unit 10A, a comparison unit 13B, and a monitored voltage generation unit 13C.

The comparison unit 13B includes a first comparison unit provided with a comparator CP1 and a resistor R11 and a second comparison unit provided with a comparator CP2 and a resistor R12. The monitored voltage generation unit 13C includes resistors R7 and R8 for generating a monitored voltage Vx1 and resistors R9 and R10 for generating a monitored voltage Vx2. The monitored voltage Vx1 is a voltage generated by resistor division of a monitored voltage Vx3 with the resistor R7 and the resistor R8. The monitored voltage Vx2 is a voltage generated by resistor division of a monitored voltage Vx4 with the resistor R9 and the resistor R10. The voltage monitoring circuit 13 inputs the monitored voltage Vx1 and the monitored voltage Vx2 to a non-inverting input terminal (+) of the comparator CP1 and a non-inverting input terminal (+) of the comparator CP2, respectively, and inputs the variable reference voltage Vref to an inverting input terminal (−) of the comparator CP1 and an inverting input terminal (−) of the comparator CP2 in common. The comparator CP1 compares the variable reference voltage Vref inputted to the inverting input terminal (−) with the monitored voltage Vx1 inputted to the non-inverting input terminal (+). The comparator CP2 compares the variable reference voltage Vref inputted to the inverting input terminal (−) with the monitored voltage Vx2 inputted to the non-inverting input terminal (+). One terminal of the resistor R11 is connected to the output side of the comparator CP1, and the voltage V2 is applied to the other terminal of the resistor R11. One terminal of the resistor R12 is connected to the output side of the comparator CP2, and the voltage V2 is applied to the other terminal of the resistor R12. Output voltages Vout1 and Vout2 are outputted from the comparators CP1 and CP2, respectively.

As shown in FIG. 15, when the monitored voltage Vx1 is between the reference voltage Vref1 and the reference voltage Vref2 (Vref 1>Vx1>Vref2), the output voltage Vout1 between the output voltages has a pulse waveform. When the monitored voltage Vx1 is equal to or higher than the reference voltage Vref1 (Vx1≥Vref1), the output voltage Vout1 is a fixed voltage at the “H” level. When the monitored voltage Vx1 is equal to or lower than the reference voltage Vref2 (Vx1≤Vref2), the output voltage Vout1 is a fixed voltage at the “L” level (GND).

Further, as shown in FIG. 15, when the monitored voltage Vx2 is between the reference voltage Vref1 and the reference voltage Vref2 (Vref1>Vx2>Vref2), the output voltage Vout2 between the output voltages has a pulse waveform. When the monitored voltage Vx2 is equal to or higher than the reference voltage Vref1 (Vx2≥Vref1), the output voltage Vout2 is a fixed voltage at the “H” level. When the monitored voltage Vx2 is equal to or lower than the reference voltage Vref2 (Vx2≤Vref2), the output voltage Vout2 is a fixed voltage at the “L” level (GND).

In the present embodiment, since the voltage monitoring circuit 13 inputs the variable reference voltage Vref to the inverting input terminal (−) of the comparator CP1 and the inverting input terminal (−) of the comparator CP2 in common, it is only necessary to provide one reference voltage generation unit, and it is possible to reduce the number of parts in comparison with the case of providing two reference voltage generation units in order to input reference voltages to the comparator CP1 and the comparator CP2.

Although the above embodiments are preferred embodiments of the present invention, the scope of the present invention is not limited only to the above embodiments. It is possible to practice the present invention in a form obtained by making various changes within a range not departing from the spirit of the present invention.

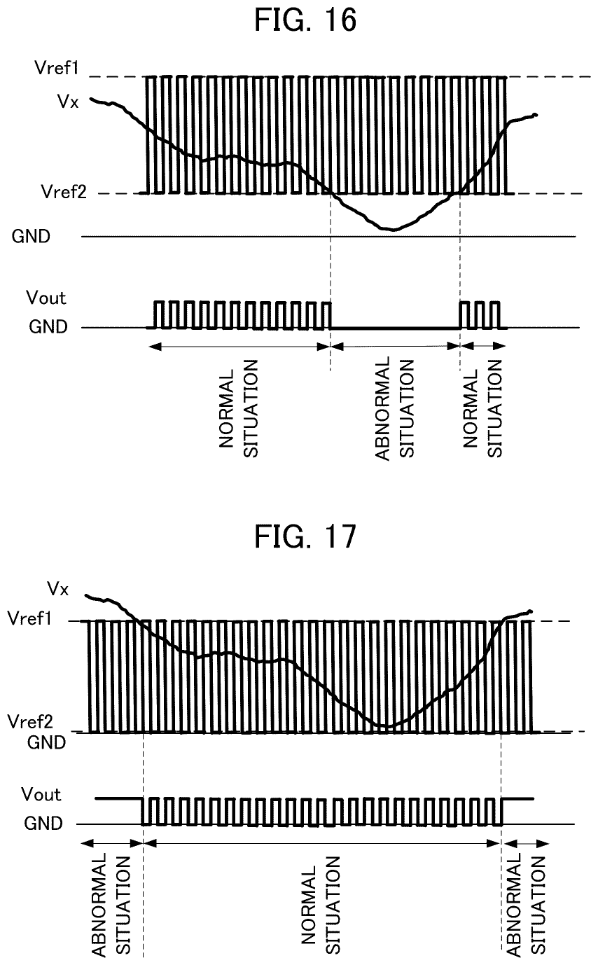

For example, although two thresholds of the reference voltage Vref1 and the reference voltage Vref2 are provided as thresholds for the variable reference voltage Vref and compared with the monitored voltage Vx in the above embodiments, any of the reference voltage Vref1 and the reference voltage Vref2 may be set as a threshold. When the reference voltage Vref1 is set to a value exceeding an upper limit of a fluctuation range of the monitored voltage Vx, the reference voltage Vref2 is set as a threshold. FIG. 16 is a waveform diagram showing operation of the voltage monitoring circuit of the first embodiment of the present disclosure when the reference voltage Vref1 is set to a value exceeding the upper limit of the fluctuation range of the monitored voltage Vx. As shown in FIG. 16, the output voltage Vout has a pulse waveform in an area of Vx>Vref2, and is GND when the monitored voltage Vx is equal to or lower than the reference voltage Vref2.

Further, when the reference voltage Vref2 is set to a value below a lower limit of the fluctuation range of the monitored voltage Vx, the reference voltage Vref1 is set as a threshold. FIG. 17 is a waveform diagram showing operation of the voltage monitoring circuit of the first embodiment of the present disclosure when the reference voltage Vref1 is set as a threshold for the reference voltage. As shown in FIG. 17, the output voltage Vout has a pulse waveform in an area of Vx<Vref1, and is at the “H” level when the monitored voltage Vx is equal to or lower than the reference voltage Vref1.

The voltage monitoring circuit and the voltage monitoring method according to the present disclosure can take various embodiments with configurations as below, including the embodiments described above.
(1) A voltage monitoring circuit (for example, the voltage monitoring circuit 10, 11, 12 or 13) includes a reference voltage generation unit (for example, the reference voltage generation unit 10A) that generates a variable reference voltage, the variable reference voltage periodically changing between a first reference voltage and a second reference voltage lower than the first reference voltage; and a comparison unit (for example, the comparison unit 10B) that compares the variable reference voltage with a monitored voltage to switch an output level based on relative magnitudes of the variable reference voltage and the monitored voltage.

According to the power source monitoring circuit, it becomes possible to determine normality/abnormality of a monitored voltage and the voltage monitoring circuit by an output of the voltage monitoring circuit, without having to provide another circuit for detecting abnormality of the voltage monitoring circuit separately from the voltage monitoring circuit.
(2) The voltage monitoring circuit according to (1) above, wherein the reference voltage generation unit generates the first reference voltage and the second reference voltage by changing a resistor divider ratio of a constant voltage.
(3) The voltage monitoring circuit according to (2) above, wherein the reference voltage generation unit includes a first resistor (for example, the resistor R1); a second resistor (for example, the resistor R2) connected to the first resistor in series; a third resistor (for example, the resistor R3) having one terminal connected to a connection point between the first resistor and the second resistor; and a switching element (for example, the MOS transistor Tr) connected to the other terminal of the third resistor; the reference voltage generation unit generates the first reference voltage by turning off the switching element and performing resistor division of the constant voltage with the first resistor and the second resistor; and the reference voltage generation unit generates the second reference voltage by turning on the switching element and performing resistor division of the constant voltage with the first resistor and a combined resistance of the second resistor and the third resistor connected in parallel.
(4) The voltage monitoring circuit according to any of (1) to (3) above, wherein the comparison unit includes a plurality of comparators (for example, the comparators CP1 and CP2) to which a plurality of monitored voltages are inputted, respectively; and the variable reference voltage is inputted in common to the plurality of comparators.
(5) The voltage monitoring circuit according to any of (1) to (3) above, wherein the comparison unit is connected to a determination circuit; and the determination circuit (for example, the determination circuit 10C or 10D) determines the monitored voltage to be normal when a voltage in a pulse waveform is outputted from the comparison unit, and determines that there is abnormality in at least one of the monitored voltage or the voltage monitoring circuit when a fixed voltage is outputted.
(6) A voltage monitoring method of a voltage monitoring circuit (for example, the voltage monitoring circuit 10, 11, 12 or 13), the voltage monitoring method including causing a switching element (for example, the MOS transistor Tr) to input a periodically changing variable reference voltage to a comparison unit (for example, the comparison unit 10B), by switching between a first reference voltage and a second reference voltage lower than the first reference voltage; and causing the comparison unit to compare the variable reference voltage with a monitored voltage to switch an output level based on relative magnitudes of the variable reference voltage and the monitored voltage.

According to the power source monitoring method, it becomes possible to determine normality/abnormality of a monitored voltage and a voltage monitoring circuit by an output of the voltage monitoring circuit, without having to provide another circuit for detecting abnormality of the voltage monitoring circuit separately from the voltage monitoring circuit.

### EXPLANATION OF REFERENCE NUMERALS

10, 11, 12, 13: voltage monitoring circuit
10A: reference voltage generation unit
SR: shunt regulator
R1, R2, R3, R4: resistor
Tr: MOS transistor
10B, 13B: comparison unit
CP, CP1, CP2: comparator
R5: resistor
10C, 10D determination circuit
13C: monitored voltage generation unit

1. A voltage monitoring circuit comprising:
a reference voltage generation unit configured to generate a variable reference voltage, the variable reference voltage periodically changing between a first reference voltage and a second reference voltage lower than the first reference voltage; and
a comparison unit configured to compare the variable reference voltage with a monitored voltage and switch an output level based on relative magnitudes of the variable reference voltage and the monitored voltage.

2. The voltage monitoring circuit according to claim 1, wherein the reference voltage generation unit generates the first reference voltage and the second reference voltage by changing a resistor divider ratio of a constant voltage.

3. The voltage monitoring circuit according to claim 2, wherein the reference voltage generation unit comprises:
a first resistor;
a second resistor connected to the first resistor in series;
a third resistor having one terminal connected to a connection point between the first resistor and the second resistor; and
a switching element connected to an other terminal of the third resistor,
the reference voltage generation unit generates the first reference voltage by turning off the switching element and performing resistor division of the constant voltage with the first resistor and the second resistor, and
the reference voltage generation unit generates the second reference voltage by turning on the switching element and performing resistor division of the constant voltage with the first resistor and a combined resistance of the second resistor and the third resistor connected in parallel.

4. The voltage monitoring circuit according to claim 1, wherein
the comparison unit comprises a plurality of comparators to which a plurality of monitored voltages are inputted, respectively, and
the variable reference voltage is inputted in common to the plurality of comparators.

5. The voltage monitoring circuit according to claim 1, wherein
the comparison unit is connected to a determination circuit; and
the determination circuit determines the monitored voltage to be normal when a voltage in a pulse waveform is outputted from the comparison unit, and determines that there is abnormality in at least one of the monitored voltage or the voltage monitoring circuit when a fixed voltage is outputted.

6. A voltage monitoring method for a voltage monitoring circuit, the voltage monitoring method comprising:
causing a switching element to input a periodically changing variable reference voltage to a comparison unit, by switching between a first reference voltage and a second reference voltage lower than the first reference voltage; and
causing the comparison unit to compare the variable reference voltage with a monitored voltage and to switch an output level based on relative magnitudes of the variable reference voltage and the monitored voltage.
